(19) United States
(12) Patent Application Publication
(10) Pub. No.: US 2010/0084761 A1
(43) Pub. Date: Apr. 8, 2010

(54) SEMICONDUCTOR DEVICE AND FABRICATION METHOD OF THE SAME

(76) Inventor: Masatoshi Shinagawa, Shiga (JP)

Correspondence Address: MCDERMOTT WILL & EMERY LLP, 600 13TH STREET, NW, WASHINGTON, DC, 20005-3096, US

(21) Appl. No.: 12/538,502

(22) Filed: Aug. 10, 2009

(30) Foreign Application Priority Data
Oct. 6, 2008 (JP) 2008-259827

(51) Int. Cl. H01L 23/367; H01L 21/60

(52) U.S. Cl. 257/706; 438/108; 438/122; 438/117; 257/712; 257/723; 257/E23.103; 257/E21.511; 257/690

(57) ABSTRACT

A semiconductor device includes a mounting substrate, a plurality of semiconductor chips mounted on the mounting substrate, and a heat-dissipation area formed above the plurality of semiconductor chips. A distance between one of the plurality of semiconductor chips which generates a greatest amount of heat and the heat-dissipation area is smaller than a distance between the other semiconductor chips and the heat-dissipation area.

### CROSS-REFERENCE TO RELATED APPLICATION

This application claims priority from Japanese Patent Application No. 2008-259827 filed on Oct. 6, 2008, which is hereby incorporated by reference in its entirety for all purposes.

### BACKGROUND

The present invention relates to a semiconductor device and a fabrication method of the same, particularly to a semiconductor device containing a plurality of semiconductor chips from which heat needs to be dissipated and a fabrication method of the same.

Size reduction and high functionality are demanded in various kinds of electronic equipment, such as mobile phones and digital still cameras. Thus, high functionality, high-speed processing, and size reduction by process shrink are demanded in semiconductor chips contained in a semiconductor device. As a result of this, the amount of heat generated by the semiconductor chips in the semiconductor device is increasing. Besides, multi-chip modules in which one semiconductor device contains a plurality of semiconductor chips are becoming essential. It is thus important to efficiently dissipate heat from the plurality of semiconductor chips.

For example, Japanese Patent Application Publication No. 10-032305 discloses a method in which, for the purpose of efficient heat dissipation from a semiconductor device containing a plurality of semiconductor chips, a heat-dissipation area includes a heat-sink cap which overlies the plurality of semiconductor chips and a heat-sink plate which is provided on the heat-sink cap.

### SUMMARY

However, the conventional method in which a heat-sink plate is provided on a heat-sink cap which overlies the semiconductor chips has a problem that the method cannot be applied to the case where the semiconductor chips have different heights. The heat-sink cap is bonded to the semiconductor chips with an adhesive. In the case where the semiconductor chips have different heights, the heat-sink cap may be bonded only to a semiconductor chip which is greater in height and may not be bonded to a semiconductor chip which is smaller in height. One way to avoid this may be to increase a thickness of the adhesive on the semiconductor chip which is smaller in height. However, reduction in heat-dissipation efficiency due to the increase in thickness of the adhesive is significant even if an adhesive having high thermal conductivity is used, since an adhesive has much lower thermal conductivity compared to a metal material.

To solve the above problems, a method is provided in which a wavy metal plate is interposed between the semiconductor chips and the heat-sink cap (see, for example, Japanese Patent Application Publication No. 2004-172489). According to this method, the heat-dissipation efficiency for a semiconductor chip which is smaller in height can be improved. However, the problem is that the wavy plate increases the thickness of the packaged semiconductor device as a whole.

The present invention is advantageous in solving the above problems and providing a semiconductor device in which sufficient heat-dissipation efficiency is ensured without increasing the thickness of the semiconductor device as a whole even in the case where the semiconductor device includes a plurality of semiconductor chips having different heights.

An example semiconductor device of the present invention is structured such that a semiconductor chip which generates a greatest amount of heart has a smallest space between its top surface and a heat-dissipation area.

Specifically, an example semiconductor device includes a mounting substrate, a plurality of semiconductor chips mounted on the mounting substrate, and a heat-dissipation area formed above the plurality of semiconductor chips, wherein a distance between one of the plurality of semiconductor chips which generates a greatest amount of heat and the heat-dissipation area is smaller than a distance between the other semiconductor chips and the heat-dissipation area.

According to the example semiconductor device, heat emitted by the semiconductor chip which generates the greatest amount of heat can be efficiently dissipated to the heat-dissipation area, such as a heat-sink member. In this case, heat-dissipation efficiency for the other semiconductor chips is lower than the heat-dissipation efficiency for the semiconductor chip which generates the greatest amount of heat. However, if the semiconductor device as a whole is considered, this structure enables efficient heat dissipation from the semiconductor chips. Moreover, it is not necessary to interpose a wavy plate between the heat-sink member and the semiconductor chips. Thus, the height of the packaged semiconductor device is not increased.

A fabrication method of an example semiconductor device includes: flip-chip bonding a plurality of semiconductor chips on a mounting substrate; positioning a thermal conductivity material on a top surface of each of the plurality of semiconductor chips; placing a heat-sink member such that the heat-sink member comes in contact with the thermal conductivity material; and at a time later than the placing the heat-sink member, determining whether or not the heat-sink member is correctly placed based on a shape of the thermal conductivity material.

Another fabrication method of an example semiconductor device includes: flip-chip bonding a plurality of semiconductor chips on a mounting substrate; and placing a heat-sink member on the mounting surface such that the heat-sink member comes in contact with a top surface of at least one of the plurality of semiconductor chips, wherein in the placing the heat-sink member, an electric current which flows through the at least one semiconductor chip to the heat-sink member is measured to check contact between the at least one semiconductor chip and the heat-sink member.

According to these fabrication methods, it is possible to easily determine whether or not the heat-sink member is correctly placed. It is thus possible to improve reliability of a semiconductor device which includes a heat-sink member, and productivity as well.

### BRIEF DESCRIPTION OF THE DRAWINGS

FIG. 1A and FIG. 1B show a semiconductor device of the first embodiment. FIG. 1A is a plan view and FIG. 1B is a cross-sectional view taken along the line Ib-Ib of FIG. 1A.

FIG. 2 shows a plan view of a modification of the semiconductor device of the first embodiment.

FIG. 3 shows plan views for explaining how to check whether or not a heat-sink cap is correctly placed in a modification of the semiconductor device of the first embodiment.

FIG. 4 shows a plan view of a modification of the semiconductor device of the first embodiment.

FIG. 5 shows a cross-sectional view of a modification of the semiconductor device of the first embodiment.

FIG. 6 shows a cross-sectional view of a modification of the semiconductor device of the first embodiment.

FIG. 7 shows a cross-sectional view of a modification of the semiconductor device of the first embodiment.

FIG. 8A and FIG. 8B show a modification of the semiconductor device of the first embodiment. FIG. 8A is a plan view and FIG. 8B is a cross-sectional view taken along the line VIIIb-VIIIb of FIG. 8A.

FIG. 9 shows a plan view of a modification of the semiconductor device of the first embodiment.

FIG. 10 shows a cross-sectional view for explaining how to check whether or not a heat-sink cap is correctly placed in a modification of the semiconductor device of the first embodiment.

FIG. 11 shows a cross-sectional view of the first modification of the first embodiment.

FIG. 12 shows a cross-sectional view of the second modification of the first embodiment.

FIG. 13 shows a cross-sectional view of the third modification of the first embodiment.

FIG. 14 shows a cross-sectional view of the fourth modification of the first embodiment.

FIG. 15A to FIG. 15C show cross-sectional views of a semiconductor device of the second embodiment.

FIG. 16 shows a cross-sectional view of a modification of the semiconductor device of the second embodiment.

### DETAILED DESCRIPTION

### First Embodiment

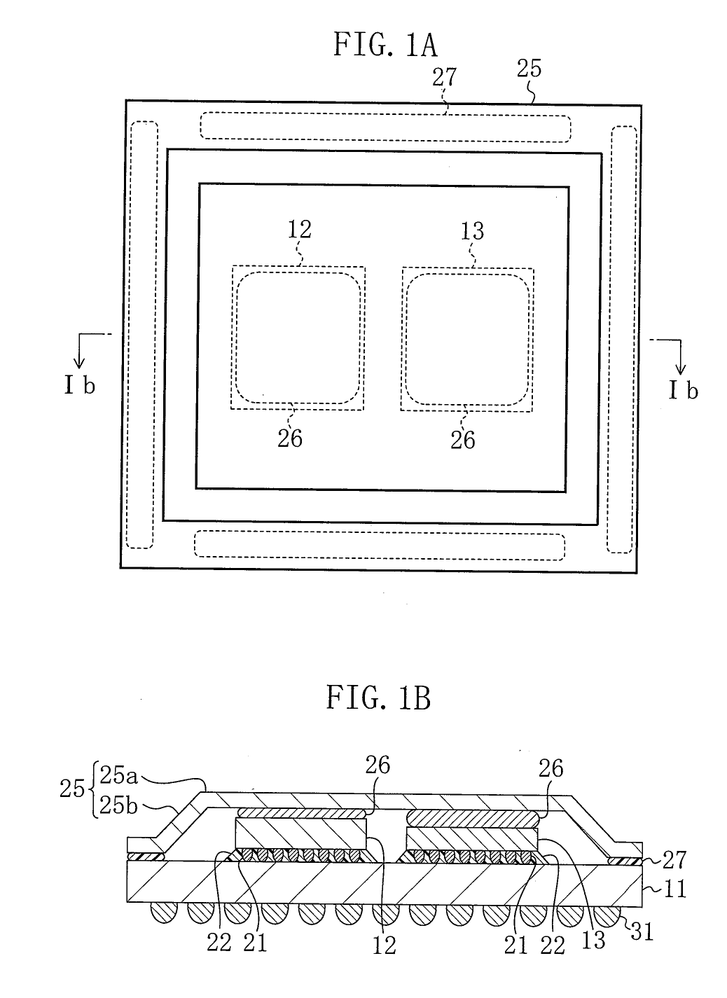

FIG. 1A and FIG. 1B show an example semiconductor device. FIG. 1A shows a structure in plan view and FIG. 1B shows a cross-sectional structure taken along the line Ib-Ib of FIG. 1A.

Referring to FIG. 1, the example semiconductor device has a structure in which a plurality of semiconductor chips are mounted on a mounting surface of a mounting substrate 11. In FIG. 1, a first semiconductor chip 12 and a second semiconductor chip 13 are flip-chip bonded to the mounting substrate 11 through bumps 21 made of such as gold or solder. The space between the mounting substrate 11 and each of the first and second semiconductor chips is filled with a sealing resin 22 for protecting the bump connection. External connection terminals 31 such as solder balls are provided on the surface opposite to the mounting surface of the mounting substrate 11 (i.e., back surface of the mounting substrate 11). The external connection terminals 31 are electrically connected to pads (not shown) of the first semiconductor chip 12 and the second semiconductor chip 13, through the bumps 21 and a wiring layer (not shown) formed on the mounting substrate 11.

A heat-sink cap 25 (a heat-sink member) is placed on the mounting surface of the mounting substrate 11 such that it covers the first semiconductor chip 12 and the second semiconductor chip 13. The heat-sink cap 25 is made of a material having high thermal conductivity, such as metal. The heat-sink cap 25 includes a top plate 25a and a support portion 25b that holds the top plate 25a. The top plate 25a is connected, through a thermal conductivity material 26, to surfaces (top surfaces) of the first semiconductor chip 12 and the second semiconductor chip 13 that are opposite to the surfaces on which the pads are provided. The support portion 25b is bonded to the mounting substrate 11 with an adhesive material 27. As described later, it is preferable that the thermal conductivity material 26 has fluid properties. The thermal conductivity material 26 may also have adhesive properties. In the case where the thermal conductivity material 26 is not an adhesive having great strength, it is preferable that an adhesive having great elasticity is used as a material for the adhesive material 27. This can ensure the adhesion of the heat-sink cap 25 to the mounting substrate 11 even if the thermal conductivity material 26 has weak or no adhesive properties.

In the example semiconductor device, the height of the first semiconductor chip 12 is greater than the height of the second semiconductor chip 13. Thus, the distance between the top plate 25a and the top surface of the first semiconductor chip 12 is smaller than the distance between the top plate 25a and the top surface of the second semiconductor chip 13. Due to this structure, heat generated by the first semiconductor chip 12 is transferred to the heat-sink cap 25 more efficiently than heat generated by the second semiconductor chip 13. If such a semiconductor chip which consumes more electric power and which generates more heat than the second semiconductor chip 13 is used as the first semiconductor chip 12, the heat-dissipation efficiency of the semiconductor device as a whole can be improved.

The above is the example in which the distance between the first semiconductor chip 12 and the top plate 25a is reduced by using, as the first semiconductor chip 12, a semiconductor chip whose height is greater than the height of the second semiconductor chip 13. The distance between the first semiconductor chip 12 and the top plate 25a may also be reduced to be smaller than the distance between the second semiconductor chip 13 and the top plate 25a, by increasing the height of the bumps 21 formed between the first semiconductor chips 12 and the mounting substrate 11.

The thermal conductivity material 26 may be applied to the top surfaces of the first semiconductor chip 12 and the second semiconductor chip 13 after flip-chip bonding. The thermal conductivity material 26 is applied to the top surface of the second semiconductor chip 13 more thickly than the thermal conductivity material 26 is applied to the top surface of the first semiconductor chip 12. It is preferable that the thermal conductivity material 26 has fluid properties to ensure the connection between the heat-sink cap 25 and the thermal conductivity materials 26 applied on the top surfaces of the first semiconductor chip 12 and the second semiconductor chip 13 even if the thickness slightly differs between the thermal conductivity materials 26. The thermal conductivity material 26 may be made into a sheet form, and then, may be attached to the top surfaces of the first semiconductor chip 12 and the second semiconductor chip 13.

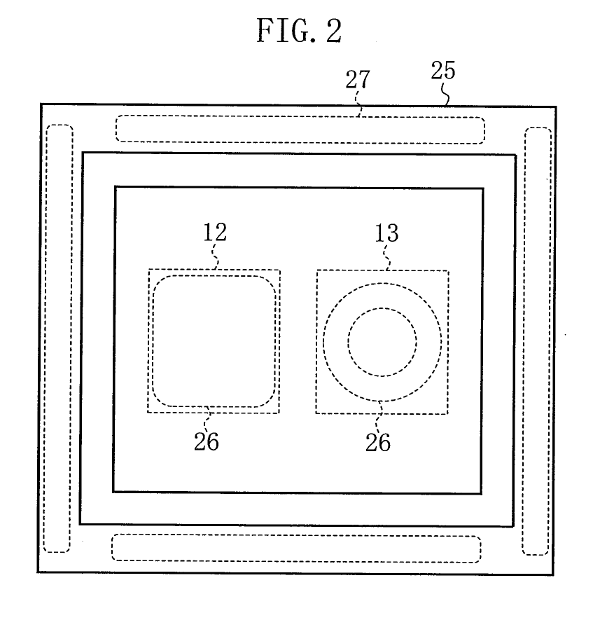

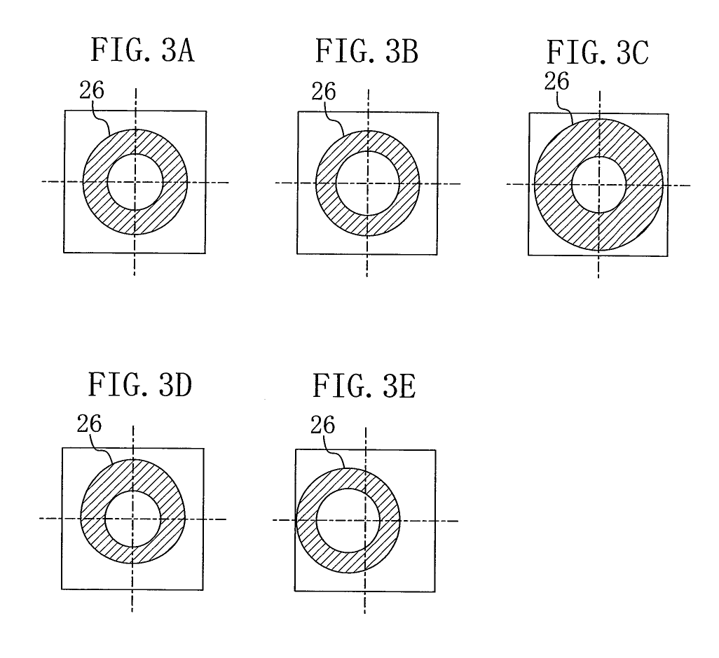

The thermal conductivity material 26 applied to the top surface of the second semiconductor chip 13 may be ring-shaped as shown in FIG. 2. Due to this structure, it is possible to check whether or not the heat-sink cap 25 is correctly placed. If the heat-sink cap 25 is correctly placed, the thermal conductive material 26 applied on the top surface of the second semiconductor chip 13 spreads uniformly as shown in FIG. 3A. If the distance between the top plate 25a of the heat-sink cap 25 and the second semiconductor chip 13 is too large, the thermal conductive material 26 spreads less as shown in FIG. 3B. If the distance is too small, the thermal conductivity material 26 spreads much as shown in FIG. 3C. If the top plate 25a of the heat-sink cap 25 is not parallel to the second semiconductor chip 13, the thermal conductivity material 26 spreads ununiformly as shown in FIG. 3D. If the heat-sink cap 25 is displaced, the spread of the thermal conductivity material 26 is off the center as shown in FIG. 3E.

The thermal conductivity material 26 has high thermal conductivity. Therefore, even if the thermal conductivity material 26 under the heat-sink cap 25 cannot be visually inspected, the above abnormal spread of the thermal conductivity material 26 can be detected by monitoring, through infrared radiation, an instantaneous change in heat increase speed when heat is applied to the semiconductor device.

According to the above advantage of the present invention, it is possible to check whether or not the heat-sink cap 15 is correctly placed, simultaneously with the placement of the heat-sink cap 25 in the fabrication process. Screening of defective devices is also possible in the fabrication process. The present invention is thus effective in improving reliability and reducing costs.

Changing the shape of the thermal conductive material 26 in plan view does not only enable checking whether or not the heat-sink cap 25 is correctly placed, but also enables changing forces applied to the first semiconductor chip 12 and the second semiconductor chip 13. Thus, greater forces can be applied to the thermal conductivity material 26 on the first semiconductor chip 12, which generates a greater amount of heat, thereby improving heat dissipation.

Changing the shape of the thermal conductive material 26 in plan view results in a reduction in the contact area between second semiconductor chip 13 and the thermal conductivity material 26 to result in reduction in heat dissipation from the second semiconductor chip 13. However, it is effective in the case where the second semiconductor chip 13 generates much smaller amount of heat than the first semiconductor chip 12 and does not require great heat dissipation.

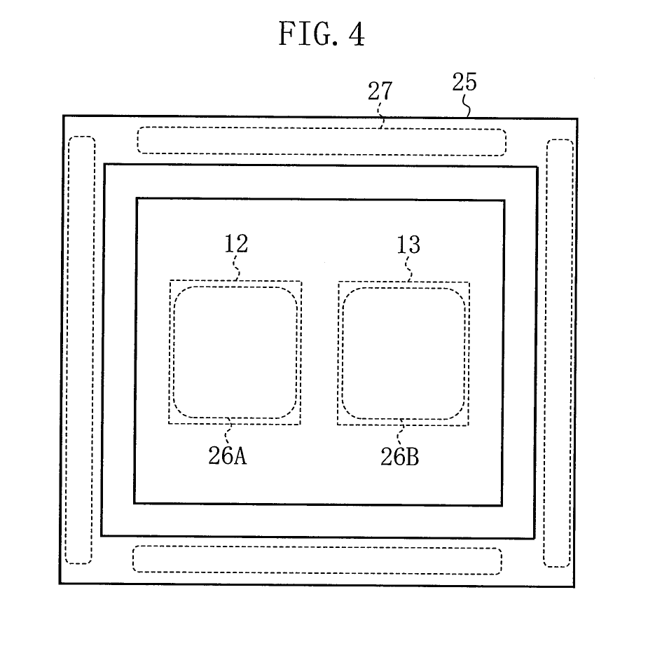

As shown in FIG. 4, the thermal conductive materials of different kinds may be used for placement on the first semiconductor chip 12 and the second semiconductor chip 13. A thermal conductivity material 26A which has weak adhesive properties but which has high thermal conductivity may be applied to the top surface of the first semiconductor chip 12. A thermal conductivity material 26B which has high elasticity and high plasticity and which has strong adhesive properties may be applied to the top surface of the second semiconductor chip 13. This can ensure a firm attachment of the heat-sink cap 25 without reducing heat dissipation from the first semiconductor chip 12.

Moreover, it is preferable that the thermal conductivity material 26A hardens more quickly than the thermal conductivity material 26B. A load for placing the heat-sink cap 25 from the above is varied according to the difference in rigidity between the thermal conductivity material 26A and the thermal conductivity material 26B. Thus, using a material which hardens more quickly than the thermal conductivity material 26B as the thermal conductivity material 26A makes it easier to check the adhesion between the first semiconductor chip 12 and the heat-sink cap 25.

If the thermal conductivity material 26 is changed as appropriate as described in the above, it enables the semiconductor chips and the heat-sink cap to be optimally placed. This is advantageous in improving heat dissipation and reliability.

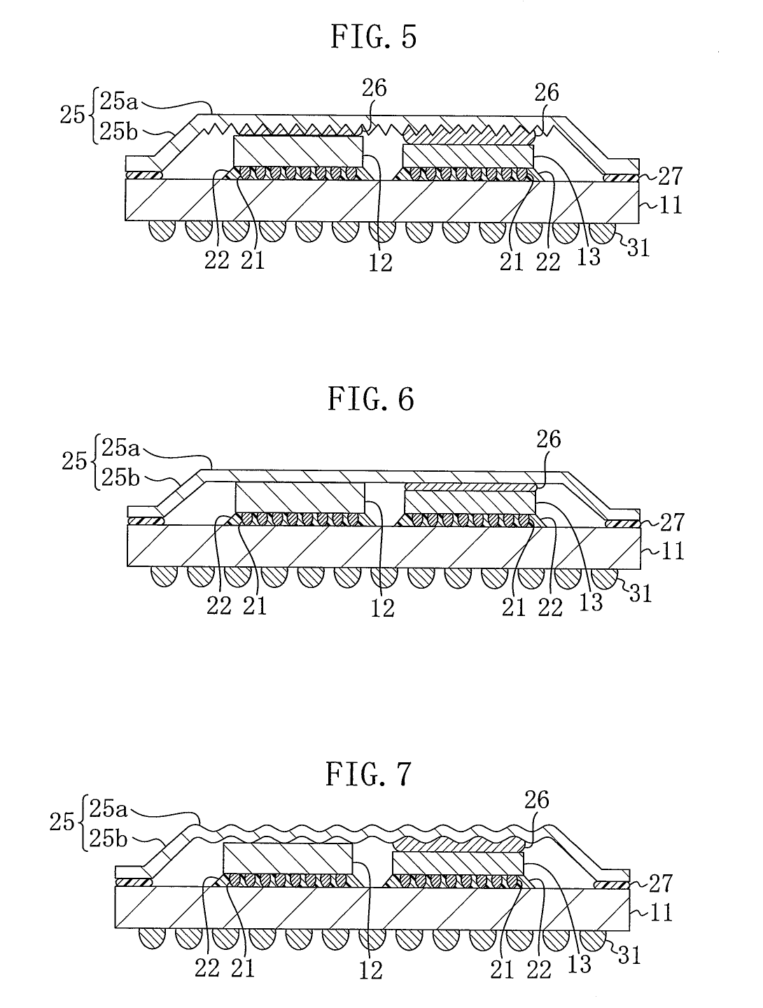

As shown in FIG. 5, the bottom surface of the top plate 25a of the heat-sink cap 25 may have irregularities. These irregularities increase the joint area between the top plate 25a and the semiconductor chips. Adhesive properties and heat dissipation can thus be improved. These irregularities also have the effect of letting the air escape, so that voids are avoided in the thermal conductivity material 26.

The effect of improving the adhesive properties and heat dissipation can be further increased by irregularities which have a fine mesh-like pattern. The irregularities can be easily formed by etching the bottom surface of the top plate 25a, or may be formed simultaneously with the formation of the heat-sink cap 25 by press working.

As shown in FIG. 6, the first semiconductor chip 12 may be in direct contact with the top plate 25a without interposing the thermal conductivity material 26. Unlike an electrical connection, heat dissipation occurs efficiently even between two members which are not in direct contact with each other. Thus, a space of several micrometers may be left between the first semiconductor chip 12 and the top plate 25a. If the space is narrow enough, heat dissipation can be increased more than in the case where the thermal conductivity material 26 is interposed between them.

Moreover, the top plate 25a may have a wavy surface. Due to this wavy surface, greater pressure can be applied to make the top plate 25a and the first semiconductor chip 12 come in contact with each other, than in the case of a flat surface. Moreover, the wavy surface increases the area of the top plate 25a, and that improves heat dissipation. Further, when a shock is applied from above the heat-sink cap 25, the wavy surface can absorb the shock to be applied to the first semiconductor chip 12.

Fabrication costs can be reduced if the top plate 25 is formed to have the wavy surface at the same time when the heat-sink cap 25 is formed by press work.

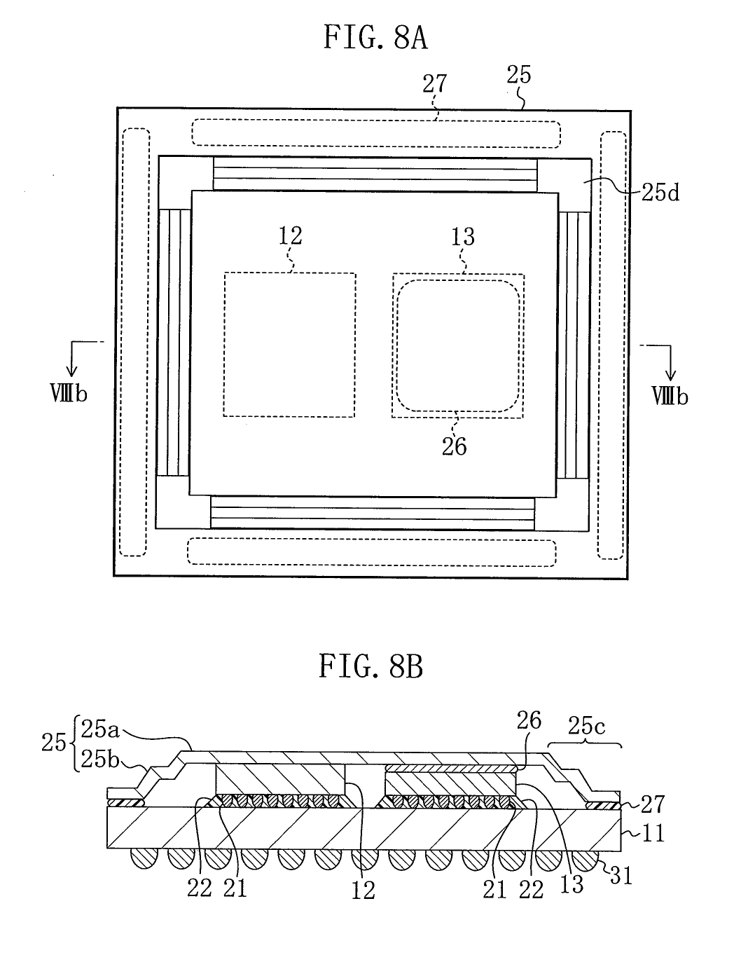

The support portion 25b of the heat-sink cap 25 may have a convex step portion 25c so that the heat-sink cap 25 may have elasticity and that the adhesiveness between the first semiconductor chip 12 and the top plate 25a may be increased. FIG. 8A and FIG. 8B show a semiconductor device in which the support portion 25b has the step portion 25c. FIG. 8A shows a structure in plan view and FIG. 8B shows a cross-sectional structure taken along the line VIIIb-VIIIb of FIG. 8A.

FIG. 8 illustrates the structure in which the top plate 25a has a flat surface. This structure increases the contact area between the first semiconductor chip 12 and the top plate 25a and hence can increase heat dissipation. The top plate 25a may also have a wavy surface.

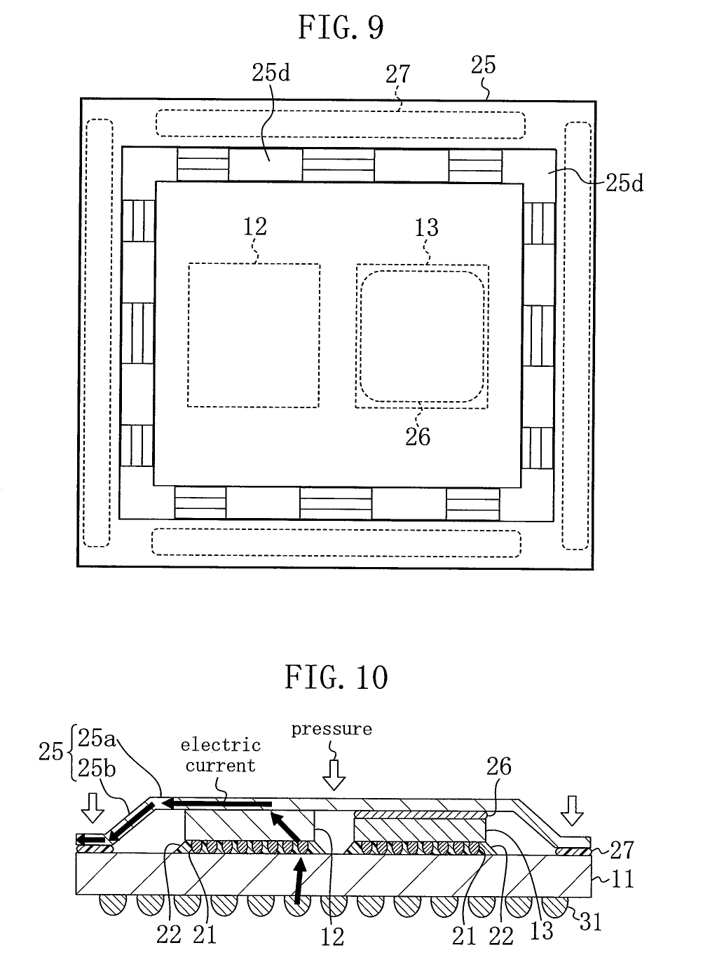

As shown in FIG. 8, the support portion 25b may have openings 25d at the four corners of the heat-sink cap 25 which is rectangular in plan view. In this structure, the step portion 25c can be easily formed by a single-direction bending work. The number of the openings 25d may be more than four as shown in FIG. 9. The elasticity of the heat-sink cap 25 can be changed by the plurality of openings 25d and easily adjusted to suitable one that does not cause any damage to the first semiconductor chip 12. Further, the openings 25d allow the air to pass through. Heat dissipation can thus be more improved.

In the case where the heat-sink cap 25 and the first semiconductor chip 12 are in direct contact with each other, the degree of contact between the heat-sink cap 25 and the first semiconductor chip 12 can be electrically checked.

The heat-sink cap 25 is bonded to the mounting substrate 11 by the pressure applied from the above. The semiconductor chips may be broken if too much pressure is applied at this time. Here, as shown in FIG. 10, one of the external connection terminals on the mounting substrate 11 is made to allow an electric current to pass through itself to the outer surface of the first semiconductor chip 12. The electric current flows between the one external connection terminal and the heat-sink cap 25 when the outer surface of the first semiconductor chip 12 and the heat-sink cap 25 come in contact with each other. It is easily decided when to stop applying pressure on the heat-sink cap 25 by measuring this electric current. Possibilities of giving damage to the first semiconductor chip 12 can thus be greatly reduced. It is also possible to check adhesion inaccuracy between the heat-sink cap 25 and the first semiconductor chip 12 after the placement of the heat-sink cap 25.

A thermal conductivity material which is an electrically conductive material and a thermal conductivity material which is an electrically insulating material may be stacked between the heat-sink cap 25 and the first semiconductor chip 12. In this case, the electrically conductive material spreads more than the electrically insulating material, according to the degree of adhesion between the heat-sink cap 25 and the first semiconductor chip 12. This allows an electric current to flow between the heat-sink cap 25 and the first semiconductor chip 12. The degree of adhesion can thus be electrically checked.

### (First Modification of the First Embodiment)

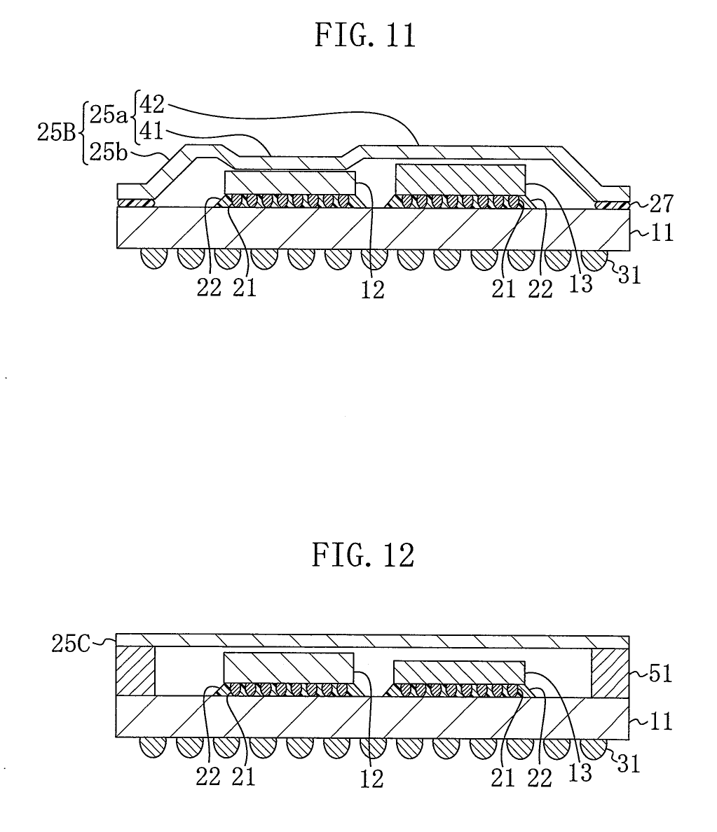

According to the first embodiment, the height of the first semiconductor chip 12 is greater than the height of the second semiconductor chip 13, and therefore, the distance between the first semiconductor chip 12 and the heat-sink cap 25 is smaller than the distance between the second semiconductor chip 13 an the heat-sink cap 25. However, a heat-sink cap 25B whose top plate 25a has a recess 41 and a protrusion 42 may also be used as shown in FIG. 11. The distance between the first semiconductor chip 12 and the heat-sink cap 25B can be smaller than the distance between the second semiconductor chip 13 and the heat-sink cap 25B by locating the recess 41 above the first semiconductor chip 12 and the protrusion 42 above the second semiconductor chip 13. According to this structure, the distance between the first semiconductor chip 12 and the heat-sink cap 25B can be smaller than the distance between the second semiconductor chip 13 and the heat-sink cap 25B even in the case where the first semiconductor chip 12 has a smaller height than the second semiconductor chip 13.

The structures described in the first embodiment, such as the structure in which a thermal conductivity material is used, and the structure in which the area of the top plate is increased by using a wavy top plate, may be applied to the present modification.

### (Second Modification of the First Embodiment)

In the first embodiment, a heat-sink cap of which the top plate and the support portion are integral with each other is used as a heat-sink member. However, the top plate and the support portion can be separate members. For example, as shown in FIG. 12, a plate-like heat-sink member 25C may be held by a supporting column 51 which is a separate member from the heat-sink member 25C. The supporting column 51 may be a metal or may be a resin, etc. According to this structure, costs of fabricating the heat-sink member can be reduced, and the chip mounting area can be increased.

Similar to the first embodiment, a thermal conductivity material may be interposed between the heat-sink member and the semiconductor chips, and the heat-sink member may have a wavy surface to increase a surface area of the heat-sink member.

### (Third Modification of the First Embodiment)

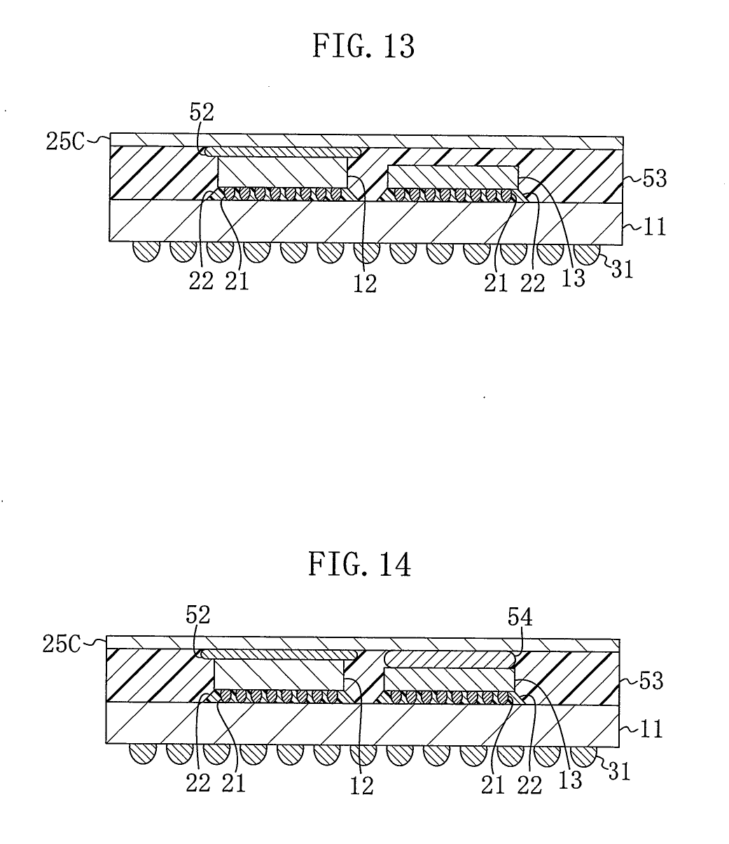

As shown in FIG. 13, the heat-sink member 25C may be held by the first semiconductor chip 12, instead of by the supporting column 51. In this case, a metal plate 52 is placed on and temporarily fixed to the top surface of the first semiconductor chip 12, and then, the space is filled with a sealing resin 53 to fix the metal plate 52. After that, the heat-sink member 25C is fixed to be in close contact with the metal plate 52. The first semiconductor chip 12 and the heat-sink member 25C are connected to each other through the metal plate 52. Thus, heat can transfer more easily from the first semiconductor chip 12 than from the second semiconductor chip 13 above which, between its top surface and the heat-sink member 25C, the sealing resin 53 is supplied. In this case, the resin can be easily supplied by using the metal plate 52 whose area is larger than the top surface of the first semiconductor chip 12 to project out, like eaves, from the top surface of the first semiconductor chip 12. In addition, such the structure can absorb the shock applied to the first semiconductor chip 12 when the heat-sink member 25C is mounted, and can reduce damage to the first semiconductor chip 12.

### (Fourth Modification of the First Embodiment)

As shown in FIG. 14, a thermal insulating part 54 made of a material whose thermal conductivity is lower than the thermal conductivity of the sealing resin 53 may be provided in the space between the second semiconductor chip 13 and the heat-sink member 25C. This structure can prevent heat dissipated from the first semiconductor chip 12 from transferring to the second semiconductor chip 13 through the heat-sink member 25C.

### Second Embodiment

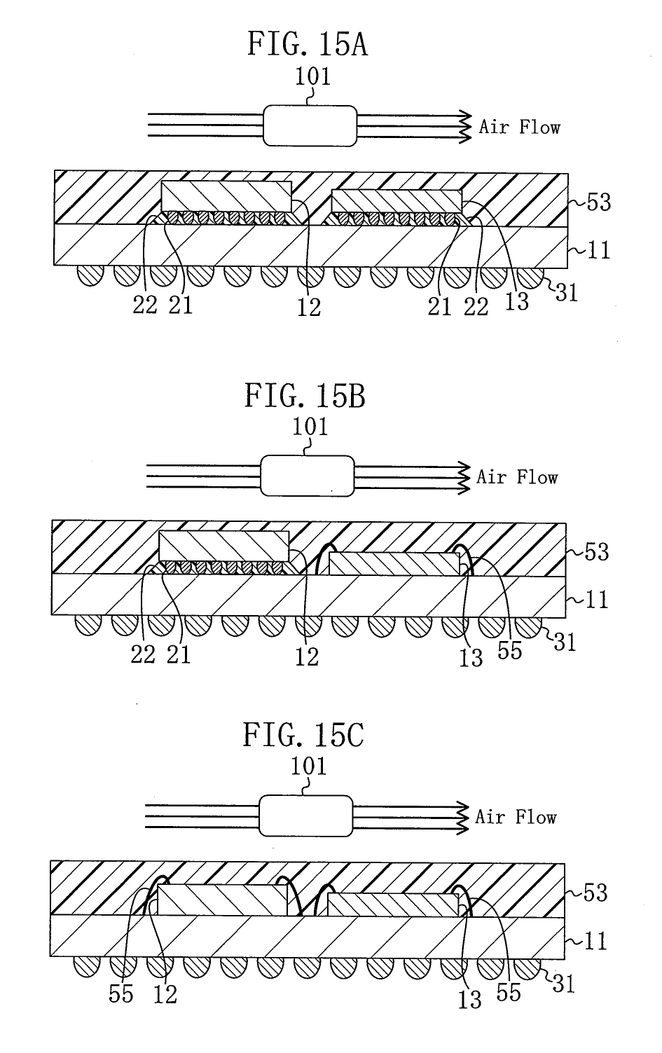

An example in which a heat-sink member made of a metal, etc. is provided is described in the first embodiment. However, the heat-sink member does not necessarily have to be provided. For example, as shown in FIG. 15A, the structure in which a heat-dissipation area 101 for dissipating heat by an air flow is provided and in which the distance between the heat-dissipation area 101 and the first semiconductor chip 12 is smaller than the distance between the heat-dissipation area 101 and the second semiconductor chip 13, may be possible. Due to this structure, heat generated by the first semiconductor chip 12 is transferred to the heat-dissipation area 101 more efficiently than heat generated by the second semiconductor chip 13. If such a semiconductor chip which consumes more electric power and which generates more heat than the second semiconductor chip 13 is used as the first semiconductor chip 12, the heat-dissipation efficiency of the semiconductor device as a whole can be improved.

The first semiconductor chip 12 and the second semiconductor chip 13 can be mounted by any method as long as the distance between the heat-dissipation area 101 and the first semiconductor chip 12 is smaller than the distance between the heat-dissipation area 101 and the second semiconductor chip 13. For example, as shown in FIG. 15B, the first semiconductor chip 12 may be flip-chip bonded and the second semiconductor chip 13 may be wire bonded using a wire 55. Both of the first semiconductor chip 12 and the second semiconductor chip 13 may be wire bonded as shown in FIG. 15C.

FIG. 15A to FIG. 15C show an example in which a sealing resin 53 covers the first semiconductor chip 12 and the second semiconductor chip 13. However, the sealing resin 53 does not have to be provided. An example in which the heat-dissipation area 101 provides air cooling is described, but the heat-dissipation area 101 may provide water cooling or may be a Peltier device, etc.

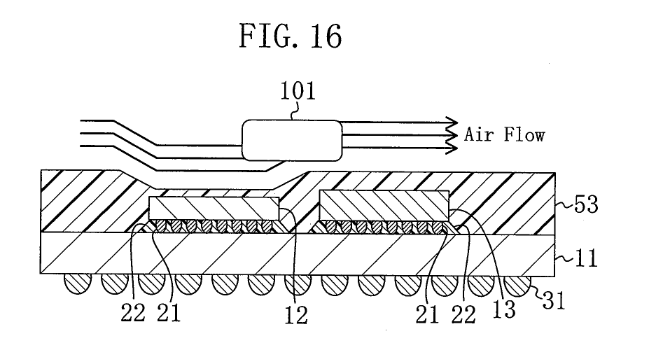

In the case where the height of the first semiconductor chip 12 which generates great heat is less than the height of the second semiconductor chip 13, the thickness of the sealing resin 53 may be reduced at a portion above the first semiconductor chip 12 as shown in FIG. 16. This structure can reduce, in effect, the distance between the heat-dissipation area 101 and the first semiconductor chip 12 to be smaller than the distance between the heat-dissipation area 101 and the second semiconductor chip 13. Heat-dissipation efficiency can be more improved if the same structure is applied to the case in which the height of the first semiconductor chip 12 is greater than the height of the second semiconductor chip 13.

For drawing simplification, thickness, length and others of each of the structural elements in the drawings may differ from those of actually-fabricated structural elements. Bumps of the semiconductor chips, connection terminals on the substrate, wiring patterns, vias and others may be omitted from the drawings, or the number of these structural elements and their shapes may be changed to illustrate them more easily.

As described in the above, a semiconductor device and a fabrication method of the same according to the present invention can achieve a semiconductor device in which sufficient heat-dissipation efficiency is ensured without increasing the thickness of the semiconductor device as a whole even in the case where the semiconductor device includes a plurality of semiconductor chips having different heights, and are useful such as for a semiconductor device which includes a plurality of semiconductor chips and a fabrication method of the same.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device comprising:
a mounting substrate;
a plurality of semiconductor chips mounted on the mounting substrate; and
a heat-dissipation area formed above the plurality of semiconductor chips, wherein
a distance between one of the plurality of semiconductor chips which generates a greatest amount of heat and the heat-dissipation area is smaller than a distance between the other semiconductor chips and the heat-dissipation area.

2. The semiconductor device of claim 1, wherein the heat-dissipation area is a heat-sink member formed above the plurality of semiconductor chips.

3. The semiconductor device of claim 1, wherein
the heat-sink member includes a top plate over the semiconductor chips, and a support portion which holds the top plate, and
the semiconductor chip which generates the greatest amount of heat has a smallest space between its top surface and a bottom surface of the top plate among the other semiconductor chips.

4. The semiconductor device of claim 3, wherein the top plate and the support portion are integral with each other.

5. The semiconductor device of claim 3, further comprising a thermal conductivity material between the top plate and each of the plurality of semiconductor chips,
wherein the thermal conductivity material provided on the semiconductor chip which generates the greatest amount of heat has a smaller thickness than the thermal conductivity material provided on the other semiconductor chips.

6. The semiconductor device of claim 5, wherein the thermal conductivity material provided on the semiconductor chip which generates the greatest amount of heat has a stacked layer structure of an electrically conductive material and an insulating material.

7. The semiconductor device of claim 3, further comprising a thermal conductivity material between the heat-sink member and each of the plurality of semiconductor chips excluding the semiconductor chip which generates the greatest amount of heat.

8. The semiconductor device of claim 7, wherein the semiconductor chip which generates the greatest amount of heat and the heat-sink member are in contact with each other.

9. The semiconductor device of claim 8, wherein the top plate has a wavy surface.

10. The semiconductor device of claim 8, wherein the support portion has a step portion and functions as a plate spring.

11. The semiconductor device of claim 10, the support portion has a plurality of openings.

12. The semiconductor device of claim 5, wherein shapes of the thermal conductivity material on the plurality of semiconductor chips in plan view are different from each other.

13. The semiconductor device of claim 5, wherein kinds of the thermal conductivity material on the plurality of semiconductor chips are different from each other.

14. The semiconductor device of claim 5, wherein the top plate has irregularities on a surface that is in contact with the thermal conductivity material.

15. The semiconductor device of claim 3, wherein the heat-sink member is bonded to the mounting substrate with an adhesive having elasticity.

16. The semiconductor device of claim 3, wherein
the top plate has a recess and a protrusion,
the recess is located above the semiconductor chip which generates the greatest amount of heat, and
the protrusion is located above the other semiconductor chips.

17. The semiconductor device of claim 2, wherein the heat-sink member is held by a metal plate on the plurality of semiconductor chips.

18. The semiconductor device of claim 17, further comprising:
a sealing resin with which a space between the heat-sink member and the mounting substrate is filled, and
a thermal insulating part which is formed between the semiconductor chips, excluding the semiconductor chip which generates the greatest amount of heat, and the heat-sink member and which is made of a material whose thermal conductivity is lower than a thermal conductivity of the sealing resin.

19. A fabrication method of a semiconductor device, comprising:
flip-chip bonding a plurality of semiconductor chips on a mounting substrate;
positioning a thermal conductivity material on a top surface of each of the plurality of semiconductor chips;
placing a heat-sink member such that the heat-sink member comes in contact with the thermal conductivity material; and
at a time later than the placing the heat-sink member, determining whether or not the heat-sink member is correctly placed based on a shape of the thermal conductivity material.

20. A fabrication method of a semiconductor device, comprising:
flip-chip bonding a plurality of semiconductor chips on a mounting substrate; and
placing a heat-sink member on the mounting surface such that the heat-sink member comes in contact with a top surface of at least one of the plurality of semiconductor chips, wherein
in the placing the heat-sink member, an electric current which flows through the at least one semiconductor chip to the heat-sink member is measured to check contact between the at least one semiconductor chip and the heat-sink member.
